(19) United States
(12) Patent Application Publication
(10) Pub. No.: US 2019/0169739 A1
(43) Pub. Date: Jun. 6, 2019

(54) AN INTERFERENCE COATING OR ITS PART CONSISTING LAYERS WITH DIFFERENT POROSITY

(71) Applicants: VALSTYBINIS MOKSLINIU TYRIMU INSTITUTAS FIZINIU IR TECHNOLOGIJOS MOKSLU CENTRAS, Vilnius (LT); LIDARIS, UAB, Vilnius (LT)

(72) Inventors: Andrius MELNINKAITIS, Vilnius (LT); Tomas TOLENIS, Vilnius (LT)

(21) Appl. No.: 16/324,750

(22) PCT Filed: Jan. 24, 2017
(86) PCT No.: PCT/IB2017/050353

§ 371 Date: Feb. 11, 2019

(30) Foreign Application Priority Data
Aug. 18, 2016 (LT) 2016 089

(51) Int. Cl. C23C 14/35; C23C 14/50; C23C 14/34; C23C 14/10; C23C 14/08; C23C 14/06; G02B 1/116

(52) U.S. Cl. CPC C23C 14/35; C23C 14/505; C23C 14/3442; C23C 14/10; C23C 14/542; C23C 14/0694; C23C 14/3414; G02B 1/116; C23C 14/081

(57) ABSTRACT

A Coating, a system of coatings and a method to produce thin film coating, deposited by a stream of particles, produced by thermal evaporation or magnetron/ion-beam sputtering, wherein the thin film coating comprises at least 3 distinct refractive index layers, out of a single target (10) material. In the process of the coating, vapor flux or particle stream is pointed obliquely to the uncovered surface of the substrate (1), which can be rotated about an axis (12), parallel to the surface of the substrate. The substrates can also be rotated about an axis (16), co-aligned with the normal vector of the substrate, to obtain an evenly deposited coating with the desired amorphous structure. The structure of the coating is selected in a pattern, which allows the porosity in-between adjacent layers to be varied. As a consequence, achieving a reflectance of the coating of at least 90% for at least one frequency radiation or polarization component.

### FIELD OF INVENTION

It is a thin film coating (or a system of coatings) and a method to produce thin film coating, which is related to material technology. More precisely, it relates to the method for achieving a high-reflectivity (HR) multilayer coating. This invention is useful because it allows tailoring of reflectivity properties by using only one source material while uniformly or discreetly modulating its density-porosity during the coating formation of this process.

### BACKGROUND OF INVENTION

Thin film multilayer coatings are formed from thin layers, whose thicknesses vary from a fraction of nanometers (e.g. the one atomic layer containing coating) to few or several micrometers. Single or multilayer coatings are widely used in high-tech field. Controlled synthesis of materials in the development of such coatings (a process that will be called deposition) is a fundamental step in many applications. During the 20th century a progress of vapor deposition technique has inspired several technological turning points in various fields, such as magnetic data storage, an electronic semiconductor equipment, light emitting diodes, optical coatings (such as high-reflectivity coatings), energy generation (e.g. thin film solar cells) and energy storage (e.g. thin-film batteries). These are just some examples of applications whose number is constantly increasing every year. The widely-used technique for the production of optical components is a surface functionalization when thin layers of different materials are used to change physical or optical properties of the component. Deposition of the anti-reflective optical coating aiming to reduce a reflection coefficient for certain wavelengths of an achromatic beam splitter that divides a light beam into two parts is a good application example for such coatings. Various filters, mirrors (e.g. semi-transparent mirrors) and polarizers also are examples of these coatings. All these optical components are using thin-film coating layers in order to control polarization, spectral, angular, spatial or other properties of light.

There are several main technologies that are used in the photonics industry for production thin-films. The simplest example is physical vapor deposition, wherein target materials are evaporated by heating them in high electrical resistance crucibles. In a vacuum environment molecules are rushed out from target to form optical thin film coating on the surface of optical component. More complex technologies include target material heating by the electron beam or the bombardment (sputtering) with high energy ion-beam. In order to make the coatings denser and more mechanically resistant, the forming surface can be densified by using additional assisting beams of accelerated ions or neutral particles.

Various technologies and techniques have been developed in order to improve the quality of these optical components. Much attention is paid to improve the resistance of such coatings to high-intensity laser irradiation, e.g. to achieve a maximum possible optical damage threshold.

One deposition method for thin high-reflectivity multilayer coatings is described in Chinese patent application No. CN201637868, published on 2010 Nov. 17. This method enables the production of high-reflectivity multilayer coatings, which consists of a substrate, a reflecting layer, and an additional composite reflective layer. The reflecting layer is arranged between the substrate and the composite reflecting layer. A complex reflecting layer consists of the first structural layer and the second structural layer. Such materials layout model allows reaching 95-100% reflectivity for wavelengths of 400-800 nanometers. This deposition method using two or more substances and may be used to improve lighting systems.

Another deposition method for increasing optical damage threshold of the high-reflectivity thin film is described in Chinese patent application No. CN102086502, published on 2011 Jun. 8. The invention solves a technical problem and increases the optical damage threshold of the high refractive index coatings by changing a film design structure and an internal quality of the deposited film. When this method is used, the plated film is very dense, absorption is small, the operation method is simple and a spectrum index is stable.

Another relevant deposition method is described in Korean patent application No. KR20150021776 published on 2015 Mar. 3. The present invention relates to the manufacturing method for anti-reflection thin film coatings. The anti-reflection thin film is formed by using a magnetron sputtering method. During this process, the porous thin film is formed in the vacuum environment when evaporation of the target material is rapid. Target material particles are vaporized in a magnetron chamber, deposited onto substrates and formed into a single layer of porous structure coating film with an excellent light transmittance. This invention is relevant, because it does not use a glancing angle deposition method, but it changes the porosity and manipulates light transmission properties of the coating.

Another manufacturing method is described in an article “Inhomogeneous thin film optical filters fabricated using glancing angle deposition”, published on 1997 May 21 in the journal “Electronics Letters” (Online No: 19970808). The article describes the target material deposition method by using the selected angle of incidence and this technique is called ‘Glancing angle deposition (GLAD)’. Glancing angle deposition is used to create a single material thin film with periodic index variation as a function (close to sinusoidal) of thickness. This method is used for fabricating inhomogeneous thin film optical interference filters, which are made using a single material and creating a close to sinusoidal refractive index modulation. Refractive index modulations are a consequence of changing porosity. The GLAD method uses a system in which the target material is deposited on a substrate by using a stream of vapor. The substrate is rotated about an axis, which is parallel to its surfaces as well as an axis, which is co-aligned with a normal vector of the substrate. This method not only provides stable growth of coatings, having a varying refractive index but also deposits coatings with a high reflection coefficient increase at the wavelength range from 430 to 480 nanometers. The measured maximal value of the reflection coefficient is 82% when the wavelength is 460 nanometers.

Another deposition method is described in the U.S. Pat. No. 5,866,204 published on 1999 Feb. 2. The method of making vapor deposited thin films by rotating the substrate in the presence of an obliquely incident vapor flux. The substrate may be rotated about an axis, which is normal to the surface of the substrate and/or parallel to the surface of the substrate by two motors mounted with their axes orthogonal to each other. The angle of incidence, measured from the normal to the surface of the substrate, exceeds 80 degrees. A feedback from a deposition rate monitor allows control of rotation speed of both motors to produce growth with a defined pattern.

Another multilayer thin film coating manufacturing method and a system that deposits high-reflectivity thin film coatings are described in the Korean patent application No. KR20090036445 published on 2009 Apr. 14. The multi-layered thin film manufacturing method comprises: a step for depositing one kind of material on the substrate; a step for changing the deposition angle by glancing angle deposition; and a step for changing the refractive index and manufacturing the thin film deposited over three layers. The multilayer thin film is coated to have the average reflection rate of 95% in an ultraviolet (UV) region and uses a metal oxide as the depositing material.

The inventions mentioned above are relevant due to their purpose—to deposit the selected material or materials on an optical component by using the desired method to change the porosity of the coating. An altered nanostructure of a layer changes optical properties of the coating. However, the prior art solutions mentioned above have obvious disadvantages, e.g. the last mentioned Korean patent describes a method is limited to use of titanium oxide as the deposition material in combination with a silver layer. The layers, which are conventionally deposited from these materials, have a crystalline structure and have a small band gap, which results in relatively low damage threshold. Such coatings would have limited applications in the high-intensity laser field. Other inventions also offer a solution only for a specific part of the spectrum or form structures of the coating, which do not improve the reflection but change other optical properties.

### SUMMARY

In order to eliminate the drawbacks indicated above, the coating or a coating system are created by using a method of the present invention, which is capable to efficiently form high-reflectivity thin film coatings by modulating porosity of its internal layers. For the deposition process, the substrate is placed in the vacuum chamber. During deposition or sputtering of the target material on the substrate or the substrate with an already existing coating, a material of only one chemical composition is deposited from one of the selected sources (targets) by discreetly or uniformly modulating (varying) the refractive index of deposited material. In the most preferred embodiment, during deposition, the formation of a structure with controlled porosity is accomplished by changing an incidence angle of material with respect to a normal of the substrate or by changing the pressure in a vacuum chamber. This coating has an amorphous structure, which allows achieving high reflection coefficient and high damage threshold. The reflection coefficient of the deposited coating is more than 90% for at least one selected wavelength range of interest or for one selected light polarization component. The thin film coating of the modulated density and the amorphous structure also can be formed by using other methods of deposition or techniques, which allow changing the coating porosity during deposition. The protection scope of this invention should not be limited by a specific method of forming the coating, a coating modulation function (a specific design) or a selected material type. The main point is that the resulting coating (or its upper part) is composed out of one material (with a band gap of E_{g}>6 eV in its dense (non-porous) state or its equivalent (corresponding to transparency region) in case of non-crystalline solid), which has an amorphous structure and defined density modulation as a function of coating thickness.

### DESCRIPTION OF DRAWINGS

FIG. 1. is a schematic representation of a thin film deposition system.

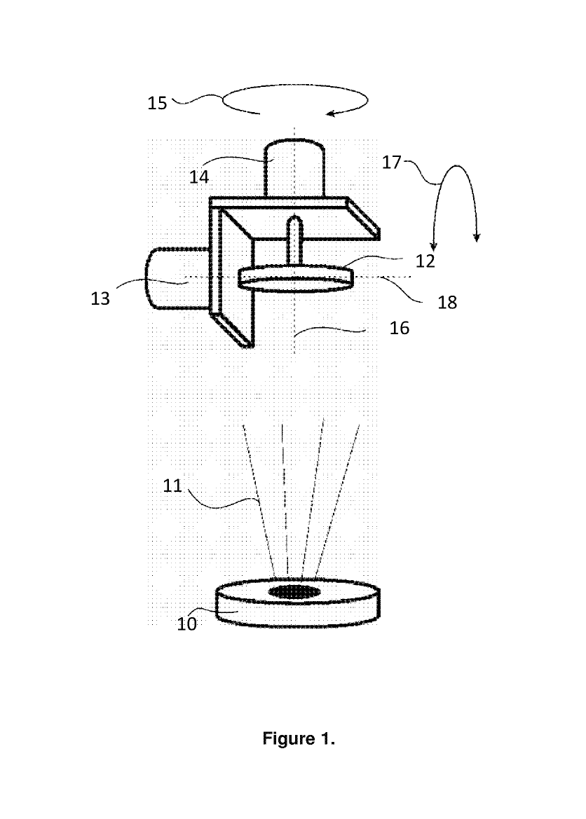

FIG. 2. is a schematic representation of an optical component, which consists of a substrate and multilayer coatings with a discreetly varying refractive index deposited onto it.

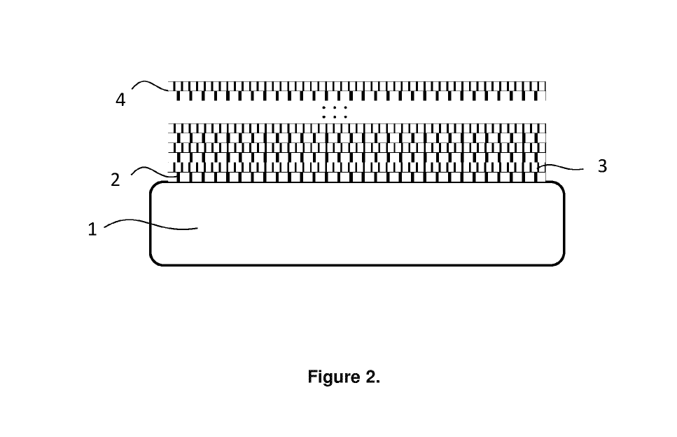

FIG. 3. is a schematic representation of an optical component, which consists of a substrate and multilayer coatings with uniformly varying refractive index deposited onto it.

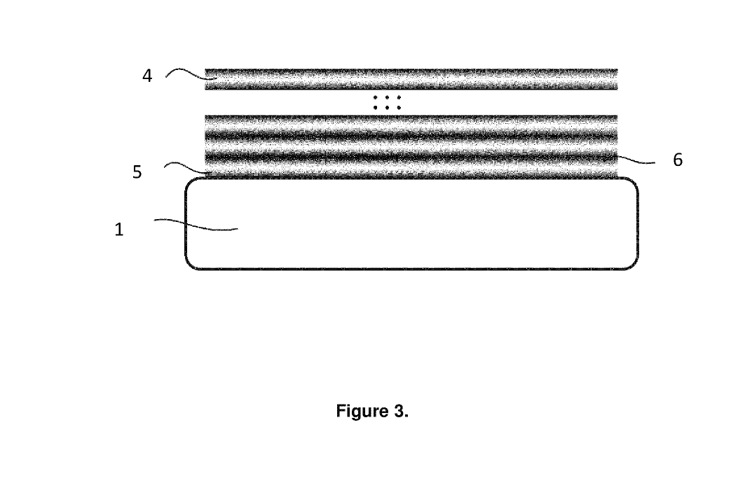

### DETAILED DESCRIPTION OF PREFERRED EMBODIMENTS

The present invention consists of a coating, a system of coatings and a method to produce thin-film high-reflectivity multilayer coatings for at least one selected wavelength range or for one selected polarization component (in case the coating is used at an angle of incidence other than 0 degrees, for example in case of polarization optics). During usage of this method, the chosen layers of material (2, 3, 4, 5, 6) are formed on a substrate (1) or on top of another type of coating in a manner, which allows changing the coating porosity. The deposited layers are formed out of a single material with varied porosity.

In the most preferred embodiment, the production method has a step in which at least one substrate of the optical component is placed in the vacuum chamber. This substrate is also known as the substrate on which the coating layers (2, 3, 4, 5, 6) will be deposited. For the sake of simplicity, optical windows, or workpieces of optical components will be referred to as substrates, which are not limited in terms of their shape, amount or material. Substrates can be mounted into holders (12), which can be arranged for insertion of multiple substrates (1). The substrate can be transparent or not to optical radiation.

A position of substrates may be changed with respect to the target (10) and the vapor stream (11) such that the desired angle between the normal vector of a substrate (1) and the vector of vapor stream (11) can be freely chosen. The values of this angle should be between 0 and 89 degrees.

The next step of this method is to rotate the substrate around an axis, which is perpendicular to the plane of the substrate (1), on which the coating is to be deposited. This substrate rotation ensures more uniform coating deposition on all points of the substrate (1) surface and more uniform distribution of the coating on different substrates if more substrates are placed in the vacuum chamber. Moreover, in the case of many substrates they are rotated around the axis (16) of the substrate holder.

In the next embodiment, many substrates (1) are placed in the substrate holder (11) so that a trajectory of planetary movement is realized, when the substrate holder rotates about its axis (16) and individual substrates or clusters of substrates rotate around a local axis (not shown in the drawings).

One of the embodiments includes the use of masks or other methods for flow homogenization.

In the most preferred embodiment, the substrates are tilted with respect to the vapor stream (11) and the amorphous nano-columnar (micro-) nano-structures are grown on them to form the coating layer. By changing the angle between the normal vector of the substrate and the vapor stream (11) the size and growth angle of self-formed nanostructures (the columns) can be changed with respect to the substrate. Upon the change of the evaporation angle, the refractive index of the formed coating layer also changes. The larger this angle is, the lower effective refractive index of the coating layer could be achieved. By gradually varying the angle between the normal vector of the substrate and the vapor stream (11) vector, the coating layer of uniformly changing or refractive index gradient can be formed. The refractive index variation is pre-defined as a function of the growing layer thickness.

In order to get the desired modulation of porosity and refractive index, other ways can be used, for example, by changing pressure in the evaporation chamber, by changing evaporation speed of target material, by controlling ion energy of bombardment or other methods mentioned herein. The particular method for controlling the porosity of the coating should not limit a scope of this invention, as a person skilled-in-the-art can use any known method for controlling the porosity or a combination of the several methods in order to obtain a similar effect.

By combining both types of the rotary movements (a rotation about the substrate normal and the angle change between the normal of the substrate and the vapor stream (11) vector) various structures of coating layers can be formed by getting the desired refractive index or its gradient.

It should be noted that in order to increase the optical damage threshold of coatings the films should be formed out of low refractive index materials (with the larger band gap) or multilayer coatings should be formed using a method, wherein layers of most resistant lower refractive index complete a conventional multilayer coating and the most damage-resistant, low refractive index layers are coated at the top: close to the coating-air interface. The intrinsic optical damage threshold of the coating layer is refractive index dependent. The difference of refractive indices between air (or another medium of the environment) and the top surface layer (4) material of the coating is directly related to optical resistance—the greater is the difference, the lower is the optical damage threshold.

In this embodiment, various technologies, which are commonly used in the industry to form optical coatings, can be used. In the simplest embodiment, the target material (10) is vaporized in a vacuum chamber by heating it in a crucible. This is called thermal evaporation.

According to the present invention, the material, which is on the substrate, can be only of one type. However, the choice of materials is wide, because for the creation of the vapor stream, various materials, such as silicon oxide, silicon, hafnium oxide, aluminum oxide, aluminum, scandium oxide, magnesium fluoride and lanthanum fluoride or any other material, which can form transparent layers, can be used. The band gap of the material of choice must be greater than 6 eV. Also, these transparent layers are characterized by an amorphous state in porous or in dense forms. Vapors of these substances are created, when the temperature reaches melting point and the conditions of vacuum are created.

In another embodiment, the target (10) material is sputtered by ion beam bombardment. The ion beam bombardment ejects atoms out of the target. A constant ion flow generates a steady stream of target material particles (11) well-defined by the mainstream.

By using this and other of the following technologies together with the above-mentioned techniques to control the porosity it is possible to form the discretely or gradually changing the refractive index of the coating when the refractive index modulation is pre-defined as the function of growing layer thickness.

In another embodiment, the target (10) material is heated by a beam of high-energy electrons. By heating the target material with the electron beam and creating vacuum environment the atoms of the target material are separated from the target surface and evaporate in all directions, like in the case of thermal evaporation. A stable flow of electrons generates a constant target vapor stream (11).

Yet in another embodiment, the target (10) material is deposited by using a magnetron sputtering method. A strong magnetic field is generated within the vacuum chamber and simultaneously, ionized gas is injected into the chamber, then ions are affected by the magnetic field, collide with the target material and eject its atoms. As a consequence, a constant vapor flow of the target material is generated (11).

An important aspect of this invention, which is related to deposition of coatings, is a permanent monitoring of coatings being formed. For this monitoring process, physical mechanisms are used and coating properties are calculated by using physical parameters and a software (hereinafter a control device). These physical mechanisms may include witness probing with a beam of white light in a reflection or transmission mode. In other embodiments, narrow-spectrum light sources, such as the light-emitting diodes or lasers, can be used for probing. In another embodiment, coating thickness can be controlled with a micro-balance weighing-machine of quartz. Since coatings are porous and have a varying density, the weight of coating layers should be converted into the thickness of the coating based on the additional measurements or a table of the values, which is established in advance. A combination of monitoring methods can also be used for any coating evaporation process. For those skilled-in-the-arts, it may be obvious to use other coatings deposition or monitoring methods and it should not narrow the scope of this invention when the high-reflectivity dielectric coating or the part of it is formed from one material by varying its porosity as the function of the coating thickness.

In one of the embodiments, by using the control device, the vapor or particle stream is pointed obliquely to the uncovered normal of the surface of the substrate (1) and an orientation of the substrate is changed with respect to the vapor stream. The control device can also generate indicative signals for coating thickness control and automatic adjustment of substrate orientation according to the selected coating structure.

In the most preferred embodiment, for growing thin film coatings, a system comprising a vacuum chamber, a target (10), an energy source (heater, electron beam, ion beam, etc.) to generate vapor or particles stream, devices (e.g. electric motors) for rotation of the substrate or group thereof about an axis (18), which is parallel to its plane and an axis (16), which coincides with a normal vector of the substrate (1) or group thereof, mounted in a holder (12), a control device for monitoring the deposition rate and providing indicative signals and for responding to them, is used. The system preferably includes a target (10) of dielectric material. It may be silicon oxide, hafnium oxide, scandium oxide, aluminum oxide, magnesium fluoride or lanthanum fluoride (or other targets which enable to form layers of a material with the band gap that is more than 6 eV and with a varying porosity). The target can also be a pure metal or a semiconductor material, which usually is not transparent and is oxidized or fluoridated by evaporating or sputtering it in the transport phase in the vacuum.

In the most preferred embodiment, the change of substrate orientation is realized by two mechanical drives (13, 14). These drives can be combined with stepper motors, DC motors or other actuators. A person skilled in mechanics can choose from a wide range of solutions, how to change the orientation of substrates with respect to the vapor stream. However, the chosen embodiment should not limit the scope of this patent protection as long as it makes it possible to change the substrate orientation in two rotational trajectories (15, 17), which are coinciding with the axes, which are passing through the substrate (16, 18). Such change of orientation can be either simultaneous or individual.

The system and the method of the most preferred embodiment are used to form amorphous nanostructured thin film coatings. More precisely, (micro or) nanostructures of several layers having columnar-spiral forms, are produced on a substrate or on an existing coating. The obtained dielectric coating consists of three or more upper layers, which are formed by evaporation of the selected target material (10). The adjacent surface layers have varied porosity, which generates different refractive indices, and thus the so-called Bragg reflection is created. By using this principle, high surface reflectivity is created. In the most preferred embodiment, the band gap of formed material layers is 6 eV or higher. It is important to note that high reflection is obtained for at least one frequency of the wave, which propagates through the coating or for one polarization component, but using this technology one can produce various optical components, for example, beam splitters, polarizers, mirrors, optical filters, and much more. The protection of present invention should not be limited to the specific types of optical components as long as an amorphous coating is formed from a single material (target) with layers of varying porosity on the optical component surface or on top of a previously formed metallic or dielectric coating.

It is very important to make sure that in this embodiment of the invention, layers of the coating do not have significant optical losses due to absorption or scattering. The latter may appear due to metal impurities (e.g. an unoxidized material), a crystalline structure of coating, an internal microstructure (an expanding columnar structure), etc. Only then the reflection can be significantly increased up to more than 90% of at least for one of the radiation wavelengths in the UV region. Some of the above-mentioned target (10) materials, such as fluorides, form not an amorphous, but micro or nano-crystalline type of coatings by using them in a normal way. In order to use these materials in the context of the present invention, during evaporation, it is necessary to take care of additional factors, which prevent the formation of crystalline structures. One of such methods is cooling of the substrate to room temperature or even lower. Another method is to bombard the growing coating with high-energy particles, which destroy the crystallites but allow the formation of porous coatings.

In the most preferred embodiment, the coating formed on the substrate or on the previously formed coating comprises layers with discretely varied refractive index. In another embodiment, the depositing layers (5, 6) do not have clear division boundary and thus a gradient refractive index variation is realized as a function of coating thickness. In this way, different coatings for various components, such as Rugate filters, mirrors, spectral or partial beam splitters and polarizers and others, may be formed. This embodiment can be realized quite easily, because the whole coating is formed from one type of the target (10) material while the porosity (respectively, the refractive index) can be changed gradually by rotating the substrate (1) or the holder of substrates (12) about an axis, which is perpendicular to the plane of substrates.

1. A multilayer dielectric coating having a refractive index modulation as a function of coating thickness, where an energy band gap of the coating material is 6 eV or higher and the refractive index modulation is realized by depositing the same target material and obtaining different porosity, characterized in that the entire coating or at least an upper surface region is formed to have an amorphous structure and a coating reflection coefficient, which is higher than 90% for at least one frequency of radiation or one polarization component.

2. The dielectric thin film coating according to claim 1, characterized in that the multilayer coating is formed from sub-layers having discretely varying refractive index and porosity.

3. The dielectric thin film coating according to claim 1, characterized in that the coating is arranged to have a continuously varying refractive index modulation, which is achieved through continuously varying coating porosity modulation, formed during the coating process.

4. The dielectric thin film coating according to claim 1, characterized in that the material of the sub-layers is silicon oxide or hafnium oxide, or aluminum oxide, or magnesium fluoride, or lanthanum fluoride, or magnesium oxide, or scandium oxide, or another transparent material having a bandgap greater than 6 eV, or a combination of these materials.

5. The dielectric thin film coating according to claim 1, characterized in that the target material is silicon, aluminum, scandium, lanthanum, magnesium, or other metal, which is oxidized or fluoridated during evaporation, in order to form the desired oxide or fluoride having the bandgap greater than 6 eV on the substrate.

6. A method of forming the dielectric coating comprising at least steps of:
providing at least one substrate or at least one substrate with a previously deposited coating,
evaporating one target material and during this process:
depositing the vaporized material onto the mentioned substrate or on the previously deposited coating, by modulating porosity and obtaining the desired refractive index modulation,
characterized in that, the newly formed coating or at least the upper part thereof, for example, three or more layers, are formed to have an amorphous structure so that reflectivity of more than 90% of the whole component would be reached for at least one radiation frequency or polarization component.

7. The method according to claim 6, characterized in that the deposited coating material is silicon oxide or hafnium oxide, or aluminium oxide, or magnesium fluoride, or lanthanum fluoride, or magnesium oxide, or scandium oxide, or other material, which is transparent to optical radiation and whose band gap is more than 6 eV.

8. The method according to claim 6, characterized in that the refractive index modulation is realized by changing the deposition angle, by rotating the substrate during target material deposition.

9. The method according to claim 6, characterized in that the deposition step includes bombardment of the coating with particles in order to obtain higher porosity, lower refractive index and destroy the crystalline structure and changing the coating material to an amorphous state.

10. The method according to claim 6, characterized in that the deposition step includes cooling at least one substrates and thereby obtaining higher porosity and a lower refractive index.

11. The method according to claim 6, characterized in that the deposition step of a single target material includes generation of vapor stream by heating the target material in a crucible.

12. The method according to claim 6, characterized in that the deposition step of a single target material includes generation of a highly energetic stream of sputtered particles by ion bombardment of the target material.

13. The method according to claim 6, characterized in that the deposition step of a single target material includes generation of vapor stream by electron heating of the target material.

14. The method according to claim 6, characterized in that the deposition step of a single target material includes generation of a stream of highly energetic particles by using magnetron sputtering.

15. An optical component comprising at least a substrate and a multilayer dielectric coating, which comprises three or more dielectric material layers, which are deposited one above the other and have a varying porosity (and refractive index, respectively), characterized in that the layers of dielectric material are formed to have an amorphous structure and the reflection coefficient of a fully formed multilayer coating is higher than 90% for at least one radiation frequency or polarization component.

16. The method according to claim 15, characterized in that at least three top layers at the interface with the environment are made of a dielectric material.
